(19) United States
(12) Patent Application Publication
(10) Pub. No.: US 2004/0091818 A1
(43) Pub. Date: May 13, 2004

(54) High resolution 3-D circuit formation using selective or continuous catalytic painting

(76) Inventors: Russell Winstead, Raleigh, NC (US); Charles Rudisill, Apex, NC (US)

Correspondence Address: BAKER & BOTTS, 30 ROCKEFELLER PLAZA, NEW YORK, NY, 10112

(21) Appl. No.: 10/292,562

(22) Filed: Nov. 12, 2002

(51) Int. Cl. G03F 7/26; G03F 7/36

(52) U.S. Cl. 430/311; 430/313; 430/314; 430/318

(57) ABSTRACT

A method of forming an electrical feature such as a 3-D circuit on a substrate is described. The method includes the following steps. A catalytic paint is first selectively deposited on the surface of a molded polymer substrate to form a paint coating of the substrate. A conductive metal such as copper or nickel is then deposited onto the coating to form a plating of the substrate. An electrical feature is then obtained by forming a precision conductive pattern in the conductive metal.

### FIELD OF THE INVENTION

The present invention relates generally to the fabrication of three-dimensional (“3-D”) circuits on molded polymer substrates. In particular, the present invention relates to a method for fabricating 3-D circuits onto molded polymer substrates using catalytic paints and subsequent patterning with photoresists.

### BACKGROUND OF THE INVENTION

Generally, circuit formation processes on 3-D polymer substrates, e.g., injection moldings, composites such as epoxy-glass, and cyanate ester, involve chemical plating of layers of metal onto the substrates. In chemical plating processes, the first step is to provide a thin electroless metallic plating such as copper or nickel to allow subsequent electroplating or electroless plating of thicker metals. For example, an initial layer of 0.000005 to 0.00005 inches of electroless copper is commonly utilized for many semi-additive and additive plating processes.

Preparation of the substrate for plating with the thin electroless metallic material, such as copper, usually involves a chemical roughening step to microscopically “pit” or “crack” the surface of the substrate. This microscopic roughening allows entrapment of the catalyst material required for electroless plating, and promotes adhesion of the plated metal layer to the substrate by mechanical interlocking. This chemical etching process utilizes severe chemicals, such as chromic-sulfuric acid, strong bases, and aggressive solvents. Additionally, many polymers, particularly unfilled homopolymers, are extremely difficult to chemically etch even with aggressive chemical treatment. In many cases, the mechanical properties and the cosmetic finish of the surface of the polymer are adversely affected by this roughening process. For example, a polymer with a shiny outer surface may lose its luster which is unacceptable for a cosmetic surface such as the outer surface of a wireless telephone cover. Plasma etching and physical abrasion processes (e.g., grit blasting) are other alternatives to surface treatment prior to initial plating, but are also problematic on many types of polymers.

Catalytic paints are used today for selective plating of electronic enclosures, primarily for electromagnetic shielding applications. These catalytic paints are typically sprayed using conventional spray equipment and techniques. The paints contain a catalyst, e.g., a palladium compound or iron phosphide, which allows the auto-catalytic deposition of a metal, such as copper or nickel, from a suitable electroless plating solution. Catalytic paints and the accompanying electroless plating solutions are commercially available from companies such as Shipley Corp. and Enthone Corp. The advantage of these paints over chemical etching of the actual substrate is that the paints are tailored to particular polymer substrates, which are well known in the art, and thus have good chemical adhesion, do not damage the substrate, and may be applied selectively, for example, to the interior of electronic device enclosures.

These catalytic paints are conventionally used for “selective metallization” in which they are sprayed with a mask on selected areas of the parts, then plated with electroless copper, typically ˜0.00005-0.0002 inches thick, and electroless nickel, typically ˜0.0005″ thick, as a passivating layer. These selective painting/plating techniques have been utilized for selective shielding of electronic components, such as the inside of cellular phone enclosures, and in limited applications, attempting to directly paint patterns for antennas and other circuitry not requiring high resolution patterns.

For precise circuit applications, the conventional mechanical masking and plating techniques, described above, do not provide high resolution, which is often required for many circuits and electrical features. For example, many antenna applications require precise control of the outline and conductor spacing of a few thousandths of an inch. Mechanical masking and spray-painting provide poor resolution, placement accuracy, limitations associated with mask design, capillary action of the paint, etc. Thus, mechanical masking and spray painting of a catalytic paint, and subsequent metal plating of the entire painted area, do not provide adequate resolution and control for most circuitry and antenna patterns.

Thus, there is a need in the art for an improved process for fabricating high resolution circuitry and other metallic patterns on polymer substrates using catalytic paints. The process should be compatible with many types of substrate materials and, additionally, should not adversely affect the mechanical properties or the physical cosmetic finish of the surface of the polymer substrate. Further, such a process should be capable of producing high resolution 3-D circuit patterning. The present invention satisfies these requirements.

### SUMMARY OF THE INVENTION

The present invention is a method of forming an electrical feature such as a 3-D circuit on a substrate. The method comprises the following steps. First, a paint which includes a catalyst, or “catalytic paint,” is selectively deposited on the surface of a molded polymer substrate to form a paint coating of the substrate. A conductive metal such as copper or nickel is then deposited onto the coating to form a plating of the substrate. An electrical feature is then obtained by forming a precision conductive pattern in the conductive metal.

The method of the present invention produces a high resolution 3-D circuit or other electrical feature on a substrate which has not been altered by the harsh techniques of chemical roughening.

### BRIEF DESCRIPTION OF THE DRAWINGS

Exemplary embodiments of the present invention will now be described in detail with reference to the accompanying drawings in which:

FIGS. 1(a)-1(d) illustrate the various stages involved in the fabrication of a 3-D molded substrate with a 3-D metallic pattern applied to the interior surface of the substrate in accordance with the present invention.

FIGS. 2(a)-2(h) illustrate the various stages involved in the formation of the conductive pattern on the interior surface of the 3-D molded substrate of FIGS. 1(a)-1(d) using a “subtractive” circuit formation process in accordance with the present invention.

FIGS. 3(a)-3(i) illustrate the various stages involved in the formation of the conductive pattern on the interior surface of the 3-D molded substrate of FIGS. 1(a)-1(d) using a “semi-additive” circuit formation process in accordance with the present invention.

FIG. 4 is a photograph of a 3-D circuit pattern of an internal wireless telephone antenna featuring 0.0005 inch thick copper formed on the substrate of the interior surface of a wireless telephone housing in accordance with the present invention; and

FIG. 5 is a photograph of the interior housing of a wireless telephone featuring a 3-D keypad circuit featuring 0.0005 inch thick copper with component pads of 8 mil lines/spaces formed on the substrate in accordance with the present invention.

### DETAILED DESCRIPTION OF THE INVENTION

The present invention provides a method for producing high resolution 3-D circuit patterning, or other electrical 3-D feature formation, on a molded polymer substrate. The method comprises selectively applying a conductive metal plating over regions of a substrate where, in a subsequent step of the method, a high resolution conductive pattern is formed. The high resolution metallic pattern may be, for example, an electronic circuit or an antenna. The method of the present invention utilizes a catalytic paint that will easily adhere to the substrate without requiring any chemical roughening that characteristically results in degradation of the cosmetic appearance or reduction in mechanical properties of the substrate.

As used herein, the term “high resolution” is used to refer to a locational tolerance of a metallic pattern on a feature of a substrate of about +/−0.001 inches to about +/−0.005 inches or less, with a feature size resolution of about 0.003 inches and the tolerance on the feature size being approx. +/−0.00025 inches. As used herein, the term “low resolution” is used to refer to a locational tolerance of a metallic pattern on a feature of a substrate of more than 0.001 inches, with a feature size resolution of about 0.010 inches and the tolerance on the feature size being greater than approx. +/−0.00025 inches.

In the first step of the preferred embodiment, a catalytic paint is selectively deposited on a molded polymer substrate to form a paint coating on the substrate. The coating may be dried or cured at an elevated temperature, such as a temperature between about 50° C. and about 100° C., or the coating may be air dried at ambient temperature. The coating is then plated by depositing a conductive metal onto the coating to form a plating. Preferably, the coating is plated by depositing the conductive metal from an electroless plating solution. More preferably, the conductive metal is copper, nickel, gold, tin, or a combination thereof. A conductive material is then precision patterned on top of the plating to form a desired 3-D circuit or electrical feature.

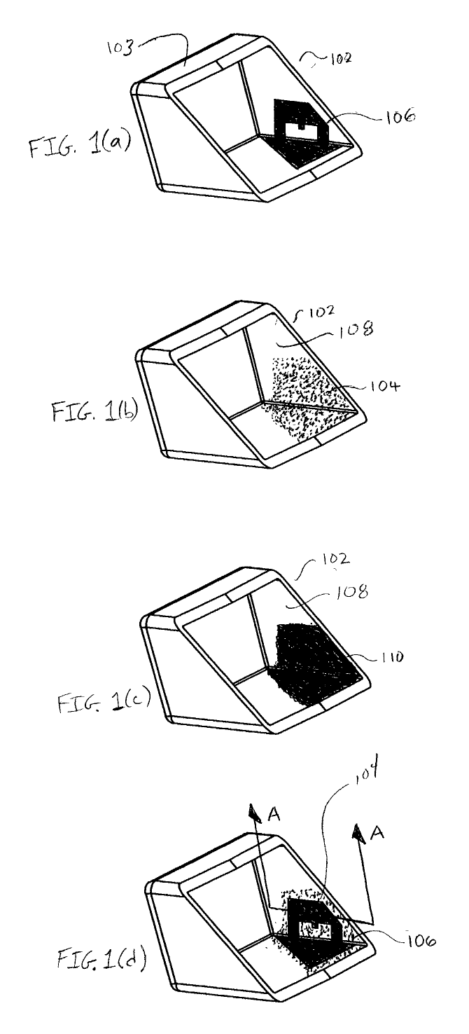

Now referring to the drawings, FIGS. 1(a)-1(d) illustrate a 3-D injection molded substrate 102 and the basic steps utilized in applying the precision conductive pattern onto the surface of the substrate 102. FIG. 1(a) illustrates the 3-D substrate 102 with a desired finished conductive pattern 106 (e.g., an antenna pattern). Typically the substrate 102 is an injection-molded polymer substrate made of materials such as, for example, polycarbonate, ABS, liquid crystal polymer, or polyetherimide. The choice of the substrate material depends upon the desired mechanical, thermal, chemical and cosmetic properties. Additionally, the outer surface of the substrate 103 may be utilized as a decorative outer cover, such as, for example, the outer cover of a wireless telephone. If used as an outer cover, the outer surface 103 must not be cosmetically degraded by the processes utilized to fabricate the conductive pattern 106.

Referring to FIG. 1(b), in accordance with a first embodiment of the present invention, a substrate 102 is first selectively painted with a catalytic paint 104 chosen based upon the material composition of the substrate 102. The entire substrate 102 need not be painted. Rather, in accordance with a preferred embodiment of the present invention, only regions of the substrate on which a circuit or other electrical feature is patterned in a subsequent step of the method are painted. As illustrated in FIG. 1(b), the conductive pattern 106 resides only on the inner surfaces 108 of the substrate 102.

The catalytic paint 104 is typically applied by spraying, using conventional spray equipment and techniques. The paint may also be applied by techniques such as pad printing, dipping, or stenciling, which are also well known in the art. The advantage of a catalytic paint over chemical etching of the actual substrate is that the catalytic paints are tailored to particular polymer substrates (well known in the art) and thus have good chemical adhesion while not damaging the substrate 102.

The application of the catalytic paint 104 may be a “coarse” selective paint application, wherein the term “coarse” is intended to indicated that the application of the catalytic paint 104 may be done with low accuracy (low resolution). The paint simply needs to cover the minimum overall area that the finished precision pattern is to occupy. A wide variety of catalytic paints are available from companies such as Shipley Corp. and Enthone Corp. These catalytic paints contain a variety of catalyst materials, such as, for example, palladium compounds, including palladium salts, or iron phosphide. The catalysts are typically dispersed in the paint's polymer matrix in the form of a fine powder. The paint's polymer matrix may include polymers such as, for example, polyurethanes, polyacrylics, and epoxy resins. The selective application of the paint results in the formation of a paint coating on the substrate. The coating is then plated by reacting the catalyst material with a suitable electroless plating solution. This reaction results in the auto-catalytic deposition of metal onto the paint coating to form a plating. The plated metal typically has very good chemical adhesion to the catalyst material. The catalytic paint's polymer matrix may be composed of many different types of polymers. The composition of the matrix depends upon the substrate type and the desired mechanical properties of the paint. For example, solvent-based matrix materials, acrylics, epoxies and urethanes may be used. Further, the matrix material may be tailored to have very good chemical and/or mechanical adhesion to the substrate. Thus, the matrix material is designed for and adheres well to the substrate, and the plating adheres well to the catalyst. These properties enable the formation of a stable plating. Catalytic paints having these properties are commercially available, and the chemistry of these paints and their associated electroless plating processes are well known to those skilled in the art. Consequently, selective catalytic painting and electroless plating allows the application of metal plating to a wide variety of substrate materials without affecting the cosmetic or mechanical properties, except at the location of the catalytic paint. Aggressive etching and surface preparation is not required as in plating directly onto the surface of the substrate with no catalytic paint layer.

Referring to FIG. 1(c), after the catalytic paint has been applied and dried, a conductive metal 110, such as copper or nickel, is then deposited on the catalytic paint from an electroless plating solution.

The conductive pattern 106 is formed by precision patterning the plating, formed as previously described, by utilizing techniques such as, for example, photolithography and laser etching. Thus, a low precision area of the substrate 102 is selectively metallized using catalytic paint 104 and electroless plating, and the high precision conductive pattern 106 is then formed in the plating formed by the plating step. In a preferred embodiment of the present invention, the precision metallic pattern 106 is formed by plating the “coarse” paint coating and patterning the plating by the use of photoresists and photoimaging or lithography techniques. A “precision” pattern is thereby formed in the originally “coarse” catalytically painted region. FIG. 1(d) shows a finished precision pattern located on the paint coating 104.

It will be understood by those skilled in the art of printed circuit board fabrication techniques that there are several varieties of photoresists, plating and metallizing sequences, materials and methods that may be utilized to form the conductive patterns. Generally, two major processes to form conductive patterns are the “subtractive” or “semi-additive” processes.

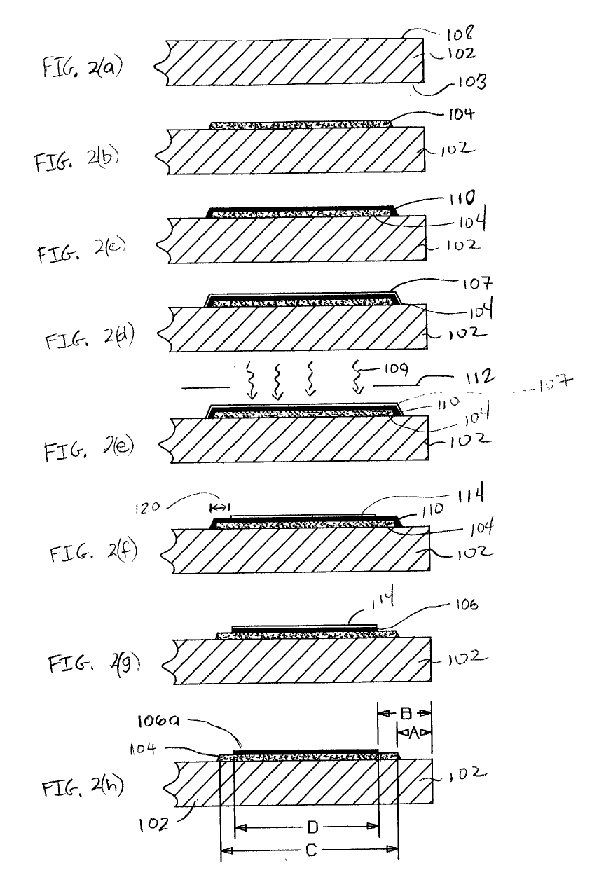

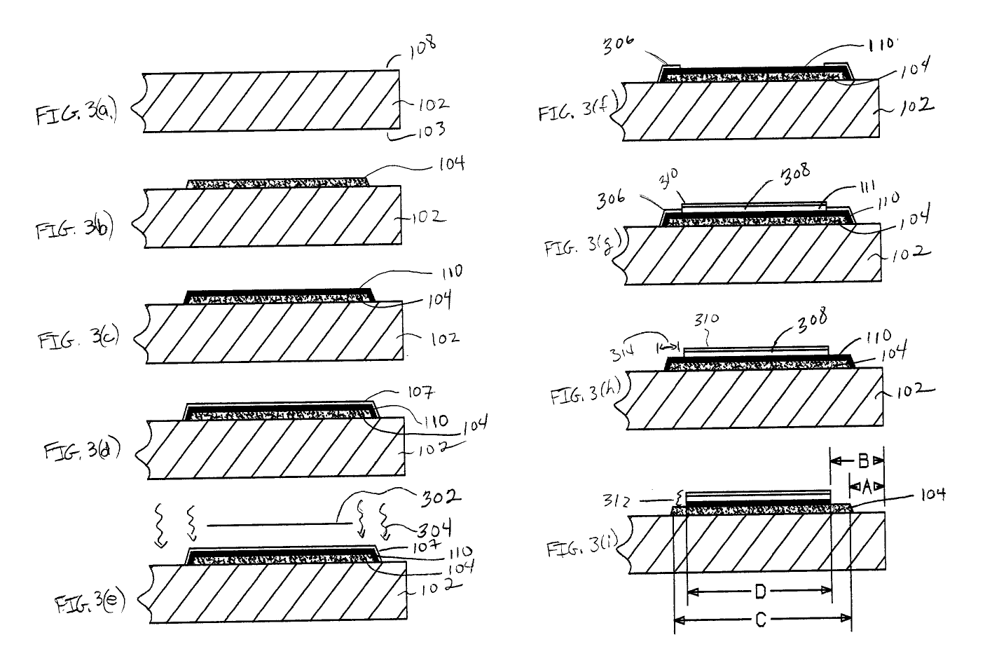

In the subtractive process, as the name implies, the conductive pattern is formed by building up the metal to the full desired thickness suitable for electroless plating or electroless plating in combination with electroplating onto the paint coating to form a plating, applying a photoresist to the plating, forming a pattern in the photoresist to define plating regions that are protected by the photoresist and plating regions that are unprotected by the photoresist, and etching the full thickness of the plating regions that are unprotected by the photoresist. FIGS. 2(a)-2(h) illustrate a subtractive process.

Referring to FIG. 2(a), FIG. 2(a) shows a cross-section of a substrate 102, typically an injection-molded polymer. In FIG. 2(b), catalytic paint 104 has been applied (e.g., by spraying) to a selected portion of the substrate 102. Defining this painted region may be accomplished at low resolution, that is, with rather coarse tolerances with respect to features such as the edge of the part 102, i.e., dimensions ‘A’ and ‘C’ in FIG. 2(h) may have a large tolerances.

In FIG. 2(c), the region painted with paint coating 104 is plated by immersing the part 102 in a suitable electroless plating solution, which deposits a layer of metallic copper or nickel, in preferably a thickness range of 0.00005 to 0.001 inches, depending upon functional requirements, onto the paint coating 104 to form a plating 110.

In FIG. 2(d), a photoresist 107 is applied to the plated region 110. The photoresist 107 may be applied by spraying the photoresist 107 onto the plating 110, dipping the plating 110 in a solution containing the photoresist 107, or electroplating the plating 110 with the photoresist 107. As shown in FIG. 2(e), the photoresist 107 is then exposed to ultra-violet (“UV”) light 109 through a mask 112, or by laser writing or laser imaging, or other forms of photolithography, to crosslink the photoresist 107 where exposed to light.

In the subsequent developing step, as shown in FIG. 2(f), photoresist 107 is removed from areas not exposed to light, and remains on areas exposed to light, producing a precision patterned photoresist area 114. The exposure of the photoresist 107 to light is done with high precision (typically within 0.003″ location tolerance and 0.001″ tolerance on the actual features of the pattern). The position of the patterned areas 114 is thus held with very good tolerance with respect to features on the substrate (see dimension ‘B’ in FIG. 2(h)) and on the overall size and shape of the pattern features (see dimension ‘D’ in FIG. 2(h)).

Referring back to FIG. 2(f), FIG. 2(f) shows the substrate 102 with plating 110 and precision photoresist pattern 114 after developing. Referring to FIG. 2(g), the copper plating 110 is etched off of the surfaces 120 not protected by the resist pattern 114, leaving patterned copper plating 106. Lastly, the photoresist 114 is stripped from the surface of the copper plating 106.

Referring to FIG. 2(h), the resulting metal pattern 106 is precisely located with respect to the substrate (dimension ‘B’) and the pattern itself precisely shaped (dimension ‘D’). The catalytic paint 104 may have more coarse tolerances (dimensions ‘A’ and ‘C’). FIGS. 2(a)-2(h) illustrate a 2-D example; however, it is understood that the patterns are usually fabricated on 3-D surfaces defined by certain molded features, edges, pins, holes etc. Typical metal layers would include copper based material, with nickel and gold passivation layers.

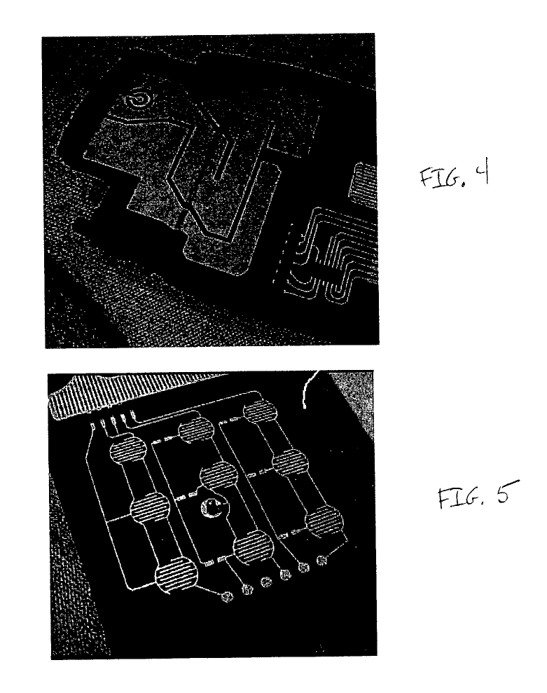

FIGS. 3(a)-3(i) illustrate the semi-additive plating process. Referring to FIG. 3(a), the base substrate 102 is molded or otherwise fabricated, and painted with catalytic paint 104 over the general area over which the conductive pattern will be placed as shown in FIG. 3(b). These two steps are identical to the subtractive process described above. Next, the catalytic paint is plated, with copper for example, in a suitable electroless plating bath with a relatively thin plating of copper 110 which is preferably 0.00003-0.00008 inches thick, as shown in FIG. 3(c). This step is different for the subtractive process in that the full thickness of desired metal suitable for electroless plating or electroless plating in combination with electroplating is not applied at this step.

Referring to FIG. 3(d), photoresist 107 is applied in the next step via spraying, dipping, electroplating, etc., to the copper layer 110. The photoresist 107 is exposed to UV light 304 on areas of the photoresist 107 that will not become part of the final pattern. This exposure may be accomplished with contact mask 302, laser writing or laser imaging, or other forms of photolithography.

Referring to FIG. 3(f), after developing, the copper is uncovered on those areas of the plating that will form the final pattern. The previously described type of photoresist is termed a “negative-acting” photoresist, where the term “negative-acting” is intended to denote that areas that are exposed to UV light are not removed during the photoresist developing process. Similar results may be obtained by using “positive-acting” photoresists, which are defined as photoresists which are removed in areas exposed to light after developing, and changing the polarity of the light during exposure. These materials and processes are well known to those skilled in the art of photolithography.

Next, a layer of conductive material 308, such as copper is plated with electroplating or electroless plating onto the original thin electroless plating 110 until the desired maximum copper thickness is reached, as shown in FIG. 3(g). The layer of conductive material may have a thickness of about 0.00025 inches to 0.0025 inches. Top metal layers 310, such as tin, a combination of tin and lead, nickel and gold layers, may be plated onto the layer of conductive material 308 at this stage. The photoresist 107 is then removed from the part 102 as illustrated in FIG. 3(h), and the background thin electroless copper plating 314 is removed by etching as shown in FIG. 3(i). The top plating material 310 (such as tin or gold) may be used as an etch resist while removing background copper plating 314. The resulting conductor pattern 312 is precisely located with respect to features on the substrate 102 (dimensions ‘B’ and ‘D’ in FIG. 3(i)), while the catalytic paint 104 may be roughly positioned on the substrate (dimensions ‘B’ and ‘C’). There are many combinations of possible plating techniques and materials and process sequences to accomplish these subtractive and semi-additive processes, as will be understood by one of ordinary skill in the art.

The result of either the semi-additive process or subtractive process is a high resolution 3-D circuit or pattern as illustrated by FIGS. 4 and 5. FIG. 4 illustrates a 3-D electrical feature of an internal wireless telephone antenna featuring 0.0005 inch copper formed on the substrate of the interior surface of a wireless telephone housing using the two step process in accordance with the present invention. FIG. 5 illustrates an interior housing of a wireless telephone featuring a 3-D keypad circuit featuring 0.0005 inch copper with component pads of 8 mil lines/spaces formed on the substrate using the two step process in accordance with the present invention. The interior housing of FIG. 4 or 5 is a bulk plated shield made out of a modified nylon material. The interior of the housing is selectively painted via spraying methods with catalytic paint

Another advantage of the present invention is the preservation of the cosmetic surface on the outside of the substrate housing (element 103 of FIG. 1(a)). Typically, conventional methods of direct plating, where the plastic substrate 102 is etched to receive the electroless plating, remove some of the gloss from the outer layer of plastic 103, thus rendering the consumer products less attractive cosmetically. Therefore, when conventional direct plating is employed, some sort of clear coat of painting operation must be performed on the cosmetic side of the substrate 103, to bring its appearance back up to standards. That step is unnecessary with the above-described methods of the present invention because there is no etching of the original plastic substrate 102, only selective catalytic painting on the inside surface 108. Thus, the subsequent plating process does not cosmetically alter the outside surface 103 of the substrate 102.

By using the methods of the present invention, either the semi-additive or subtractive processes, high resolution 3-D circuits or other electrical features can be formed directly on a molded polymer substrate without disturbing the mechanical or physical characteristics of the substrate.

Although the present invention has been described in detail with reference to specific exemplary embodiments thereof, various modifications, alterations and adaptations may be made by those skilled in the art without departing from the spirit and scope of the invention. It is intended that the invention be limited only by the appended claims.

We claim:

1. A method of forming an electrical feature on a substrate, said method comprising:
(a) selectively depositing on a substrate a paint comprising a plating catalyst to form a paint coating on the substrate,
(b) depositing a conductive metal onto the paint coating to form a plating, and
(c) forming a precision conductive pattern in the conductive metal to obtain the electrical feature.

2. The method of claim 1, wherein in step (b) said conductive metal is deposited onto the paint coating from an electroless solution to form an electroless plating, and wherein said forming a precision conductive pattern in step (c) comprises:
(i) applying a photoresist to said electroless plating,
(ii) imaging said photoresist to form exposed regions of the photoresist and unexposed regions of the photoresist,
(iii) removing said unexposed regions of the photoresist to define regions of the electroless plating unprotected by the photoresist, and
(iv) etching said regions of the electroless plating unprotected by the photoresist.

3. The method of claim 2, wherein said conductive metal is copper and the electroless plating is an electroless copper plating.

4. The method of claim 3, wherein said electroless copper plating has a thickness ranging from 0.00005 inches to 0.001 inches.

5. The method of claim 2, wherein said conductive metal is nickel and the electroless plating is an electroless nickel plating.

6. The method of claim 5, wherein said electroless nickel plating has a thickness ranging from 0.00005 inches to 0.001 inches.

7. The method of claim 2, wherein said conductive metal is gold and the electroless plating is an electroless gold plating.

8. The method of claim 7, wherein said electroless gold plating has a thickness ranging from 0.00005 inches to 0.001 of an inches.

9. The method of claim 2, wherein said conductive metal is tin and the electroless plating is an electroless tin plating.

10. The method of claim 9, wherein said electroless tin plating has a thickness ranging from 0.00005 inches to 0.001 inches.

11. The method of claim 2, wherein said imaging step comprises laser writing.

12. The method of claim 2, wherein said imaging step comprises contact masking.

13. The method of claim 2, wherein said imaging step comprises photolithography.

14. The method of claim 1, wherein in step (b) said conductive metal is deposited onto the paint coating from an electroless solution to form an electroless plating, and wherein said forming a precision conductive pattern in step (c) comprises:
(i) applying a photoresist to said electroless plating,
(ii) imaging said photoresist to form exposed regions of the photoresist and unexposed regions of the photoresist,
(iii) removing said unexposed regions of the photoresist to define first regions of the electroless plating unprotected by the photoresist,
(iv) plating the first regions of the electroless plating unprotected by the photoresist with a layer of conductive material,
(v) removing said exposed regions of the photoresist to define second regions of the electroless plating unprotected by the photoresist; and
(vi) etching said second regions of the electroless plating unprotected by the photoresist.

15. The method of claim 14, wherein the first regions of the electroless plating are plated with a layer of conductive material in step (c)(iv) by electroplating.

16. The method of claim 14, wherein the layer of conductive material plated in step (c)(iv) has a thickness of about 0.00025 inches to 0.0025 inches.

17. The method of claim 14, wherein the conductive metal deposited in step (b) is copper and the electroless plating is an electroless copper plating.

18. The method of claim 17, wherein said electroless copper plating has a thickness ranging from about 0.00003 inches to about 0.00008 inches.

19. The method of claim 14, wherein said conductive metal deposited in step (b) is nickel and the electroless plating is an electroless nickel plating.

20. The method of claim 19, wherein said electroless nickel plating has a thickness ranging from about 0.00003 inches to about 0.00008 inches.

21. The method of claim 14, wherein said conductive metal deposited in step (b) is gold and the electroless plating is an electroless gold plating.

22. The method of claim 21, wherein said electroless gold plating has a thickness ranging from about 0.00003 inches to about 0.00008 inches.

23. The method of claim 14, wherein said conductive metal deposited in step (b) is tin and the electroless plating is an electroless tin plating.

24. The method of claim 23, wherein said electroless tin plating has a thickness ranging from about 0.00003 inches to about 0.00008 inches.

25. The method of claim 14, wherein said imaging step comprises laser writing.

26. The method of claim 14, wherein said imaging step comprises contact masking.

27. The method of claim 14, wherein said imaging step comprises photolithography.

28. The method of claim 14, further comprising depositing a top metal layer on said layer of conductive material.

29. The method of claim 28, wherein said top metal layer is a layer of a material selected from the group consisting of tin, nickel, gold, and a combination of tin and lead.

30. The method of claim 1, wherein the paint coating in step (a) is formed at low resolution.

31. The method of claim 1, wherein said plating catalyst comprises a material selected from the group consisting of palladium compounds and iron phosphide.
